(19) United States
(12) Patent Application Publication
(10) Pub. No.: US 2006/0246720 A1
(43) Pub. Date: Nov. 2, 2006

(54) Method to improve thermal stability of silicides with additives

(76) Inventors: Chii-Ming Wu, Taipei (TW); Shih-Wei Chou, Taipei (TW); Cheng-Tung Lin, Jhudong Township (TW); Chih-Wei Chang, Hsin-Chu (TW); Shau-Lin Shue, Hsin-Chu (TW)

Correspondence Address: SLATER & MATSIL, L.L.P., 17950 PRESTON ROAD, SUITE 1000, DALLAS, TX, 75252, US

(21) Appl. No.: 11/117,152

(22) Filed: Apr. 28, 2005

(51) Int. Cl. H01L 21/4763; H01L 21/44

(52) U.S. Cl. 438/650; 438/656

(57) ABSTRACT

A semiconductor method of manufacture involving suicides is provided. Embodiments comprise forming a stacked arrangement of layers, the stacked arrangement of layers comprising an additive layer on a substrate, and a metal layer on the additive layer, annealing the stacked arrangement of layers to form a metal silicide layer on the substrate, wherein the metal silicide layer includes an additive from the additive layer. Alternative embodiments include etching the stacked arrangement of layers to remove an unreacted material layer. In an alternative embodiment, the stacked arrangement of layer comprises a metal layer on a substrate, an additive layer on the metal layer, and an optional oxygen barrier layer on the additive layer. An annealing process forms a metal silicide containing an additive. Metal silicides formed according to embodiments are particularly resistant to agglomeration during high temperature processing.

### TECHNICAL FIELD

This invention relates generally to semiconductor fabrication and more particularly to methods for forming silicides having improved thermal stability with less agglomeration.

### BACKGROUND

Metal silicide contacts are widely used in today's metal oxide semiconductor (MOS) technology. As device size continues to shrink, the self-aligned silicide, or salicide process, is used to reduce both the source/drain resistance and the gate resistance. In a salicide process, a metal is deposited over and reacts with the exposed silicon in the source and drain regions and the polysilicon in the gate region to form a silicide. The unreacted metal is removed by etching, which leaves the silicides on the respective source and drain regions and the polycide on the polysilicon gate. Since a masking step is not required for etching the unreacted metal from the reacted metal portions, the silicide process is termed, self-aligned.

Titanium has been frequently used in the past to form titanium salicide (TiSi₂) in gate regions on substrates; however, titanium salicide manifests problems as the source/drain junction decreases to widths of less than 200 nm. Because the silicide thickness may be only several hundred angstroms in an ultra-shallow junction, the etch selectivity of TiSi₂ to boro-phosphorsilicate glass (BPSG) may not be high enough for the TiSi₂ source/drain to withstand the contact etch.

Cobalt has also been frequently used to form cobalt salicide (CoSi₂). CoSi₂ salicides, however, have been found to have serious drawbacks and limitations as well; especially as design rules decrease to 0.1 micron and below. For example, CoSi₂ salicides often have sporadically high parasitic current leakage paths including junction and diode leakage. One factor contributing to increased junction leakage in the use of CoSi₂ is the roughness of the interface at the CoSi₂/silicon interface caused by uneven Co diffusion into the silicon substrate.

In light of these problems, workers in the art have considered other silicide materials. For example, NiSi has many superior properties over CoSi₂ and TiSi₂. NiSi has a relatively lower processing temperature, it consumes less of the silicon substrate, it has low resistivity, and it forms a lower stress interface. However, one major problem is the tendency of many silicides to agglomerate when subjected to high temperature processing. Agglomeration disrupts the continuity of a silicide film, thereby significantly increasing sheet resistance and degrading device performance. While this was a problem with conventional silicides such as CoSi₂ and TiSi₂, the problem has proven to be a more formidable process integration challenge with other silicides including NiSi.

Workers in the art know that solid-state phase changes and solid-state reactions may cause silicide agglomeration. In the case of nickel silicide, the conversion of NiSi to NiSi₂ causes agglomeration. Since these phase changes and chemical reactions are temperature dependent, workers commonly refer to a silicide having a tendency to agglomerate as being thermally unstable.

It has been found that certain additives can improve silicide thermal stability. Current approaches include incorporating the nitrogen into the silicon substrate and polysilicon gate before or after deposition of the metal silicide to retard silicide agglomeration during subsequent rapid thermal anneal (RTA) processes. However, many process integration issues remain unresolved, as these approaches have been shown to adversely affect device performance and gate oxide integrity.

Recently, X-P. Qu, et al. in a paper entitled “Thermal Stability, Phase and Interface Uniformity of Ni-silicide formed by Ni—Si Solid-state reaction,” Thin Solid Films, 462-463 (2004) 146-150, which is incorporated herein by reference in its entirety, reported the effect of additives on silicide film stability. Qu et al. found that Pt and Pd increase the thermodynamic nucleation barrier to NiSi₂ formation, thereby improving the stability of the NiSi phase. They did not examine, however, any of the process integration issues concerning deep sub-micron MOSFET manufacturing.

Recent work suggests that silicide additives are a potentially promising solution to problems relating to thermal instability and agglomeration. However, there still remains a need for methods and structures that integrate such additives into advanced semiconductor fabrication technology.

### SUMMARY OF THE INVENTION

These and other problems are generally solved or circumvented and technical advantages are generally achieved by preferred embodiments of the present invention that provide an improved method of forming metal silicides by using additives to prevent agglomeration.

Embodiments of the invention include a method for fabricating a metal silicide. Embodiments comprise forming a stacked arrangement of layers. In an embodiment, the stacked arrangement of layers comprises an additive layer and a metal layer over a substrate. In another embodiment, the stacked arrangement of layers comprises an additive layer on a substrate, and a metal layer on the additive layer. In an alternative embodiment, the stacked arrangement of layers comprises a metal layer on a substrate, an additive layer on the metal layer, and an optional oxygen barrier layer on the additive layer.

Preferred embodiments include annealing the stacked arrangement of layers to form a metal silicide layer on the substrate, wherein the metal silicide layer includes an additive from the additive layer. Alternative embodiments include etching the stacked arrangement of layers to remove an unreacted material layer.

In alternative embodiments, the additive layer comprises a material selected from the group consisting essentially of C, Al, Si, Sc, Ti, V, Cr, Mn, Fe, Co, Ni, Cu, Ge, Y, Zr, Nb, Mo, Ru, Rh, Pd, In, Sn, La, Hf, Ta, W, Re, Ir, Pt, Ce, Pr, Nd, Sm, Eu, Gd, Th, Dy, Ho, Er, Tm, Yb, Lu, Zr, and combinations thereof.

In a preferred embodiment, the metal silicide comprises cobalt silicide. In another preferred embodiment, the metal silicide comprises nickel silicide. Titanium is a preferred additive.

Metal silicides formed according to embodiments are particularly resistant to agglomeration during high temperature processing. High temperature processing may include forming a CMOS device.

Additional features and advantages of embodiments of the invention will be described hereinafter, which form the subject of the claims of the invention. It should be appreciated by those skilled in the art that the specific embodiments disclosed might be readily utilized as a basis for modifying or designing other structures or processes for carrying out the purposes of the present invention. It should also be realized by those skilled in the art that such equivalent constructions and variations on the example embodiments described do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is cross sectional view of a CMOS device at an intermediate step in a fabrication process illustrating an embodiment of the invention;

FIG. 2 is a cross sectional view of a CMOS device at an intermediate step in a fabrication process illustrating an alternative embodiment of the invention; and

FIG. 3 is a cross sectional view of a CMOS device illustrating silicide formation according to an embodiment of the invention.

Corresponding numerals and symbols in the different figures generally refer to corresponding parts unless otherwise indicated. The figures are drawn to clearly illustrate the relevant aspects of the preferred embodiments and are not necessarily drawn to scale. To more clearly illustrate certain embodiments, a letter indicating variations of the same structure, material, or process step may follow a figure number.

### DETAILED DESCRIPTION OF ILLUSTRATIVE EMBODIMENTS

The operation and fabrication of the presently preferred embodiments are discussed in detail below. However, the embodiments and examples described herein are not the only applications or uses contemplated for the invention. The specific embodiments discussed are merely illustrative of specific ways to make and use the invention, and do not limit the scope of the invention or the appended claims.

This invention relates generally to semiconductor device fabrication and more particularly to a structure and method for improved resistance silicide agglomeration during high temperature processing. The present invention will now be described with respect to preferred embodiments in a specific context, namely the creation of a CMOS device having metal silicide contacts. It is believed that embodiments of this invention are particularly advantageous when used in this process. It is further believed that embodiments of this invention are advantageous when used in other semiconductor fabrication applications as well. Therefore, the specific embodiments discussed are merely illustrative of specific ways to make and use the invention, and do not limit the scope of the invention.

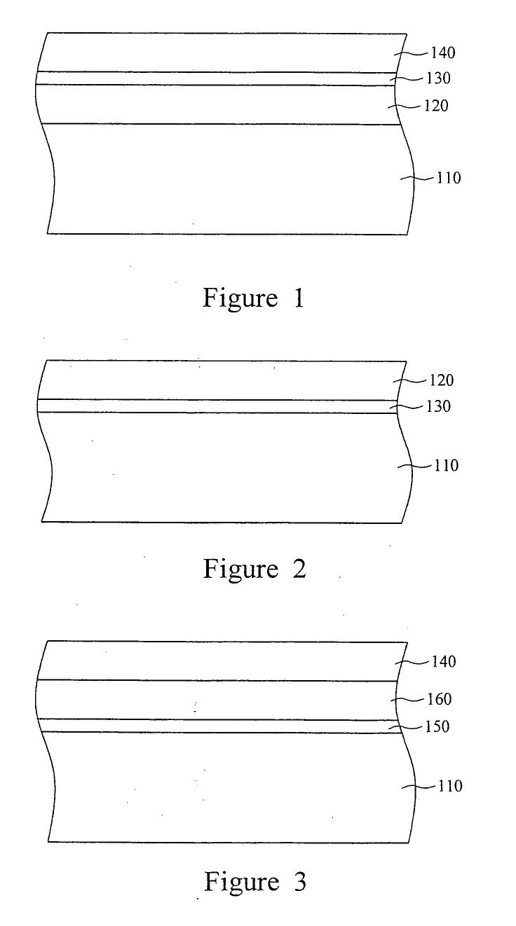

Turning now to FIG. 1, there is illustrated a cross sectional view of a CMOS device at an intermediate manufacturing step. FIG. 1 includes a semiconductor substrate 110, which preferably contains silicon. The substrate 110 may alternatively comprise Si, Ge, SiGe, strained silicon, silicon on insulator (SOI), germanium on insulator (GOD), a stacked arrangement of layers such as Si/SiGe, or a combination thereof. The substrate 110 may contain various isolation and/or device regions. These regions are not shown in the drawings of the present invention but are nevertheless intended to be included therein.

Embodiments of the invention preferably include, forming over the substrate 110, a stacked arrangement of layers, wherein the stacked arrangement of layers comprises an additive layer 130 and a metal layer 120. In an embodiment, the metal layer 120 is formed on the substrate 110 using a conventional deposition processes, preferably at a deposition pressure less than about 10 mTorr and at a temperature less than or equal to room temperature. Suitable methods include chemical vapor deposition, plasma-assisted chemical vapor deposition, evaporation, atomic layer deposition, plasma-assisted atomic layer deposition, or sputtering. Metal layer 120 may consist of Co, Ni, Ti, Pt, Pd or combinations thereof. Metal layer 120 preferably comprises a material selected from the group consisting of Co, Ti, Ni, and combinations thereof. Preferably, metal layer 120 is between about 1 and 50 nm thick, and more preferably about 10 nm thick.

In the embodiment illustrated in FIG. 1, the additive layer 130 is about 0.3 to 30 nm thick and formed on metal layer 120. The additive layer 130 preferably includes a material, which when combined with a silicide, hinders high temperature silicide agglomeration. The additive layer 130 comprises a material selected from the group consisting essentially of C, Al, Si, Sc, Ti, V, Cr, Mn, Fe, Co, Ni, Cu, Ge, Y, Zr, Nb, Mo, Ru, Rh, Pd, In, Sn, La, Hf, Ta, W, Re, Ir, Pt, Ce, Pr, Nd, Sm, Eu, Gd, Th, Dy, Ho, Er, Tm, Yb, Lu, Zr, and combinations thereof. Preferred additives comprise a material selected from the group consisting essentially of Ni, Co, Ti, Pd, Pt, Ta, Ge, Ir, Zr, and combinations thereof.

Preferably, the metal layer 120 and additive layer 130 do not include the same component. For example, when metal layer 120 includes Co, additive layer 130 preferably includes an additive other than Co.

Continuing with FIG. 1, formed on the additive layer 130 is an optional oxygen barrier layer 140. Suitable oxygen barrier layers 140 are titanium nitride, silicon nitride, tungsten nitride, tantalum nitride, and combinations thereof. The oxygen barrier layer 140 is formed using conventional deposition processes, and is about 1 to 30 nm thick, preferably about 150 nm. Suitable methods include chemical vapor deposition, plasma-assisted chemical vapor deposition, sputtering, evaporation, plating, spin-on coating and other deposition processes.

In an embodiment of the invention, the metal layer 120 comprises 1.5 nm thick Ti, the additive layer 130 comprises 15 nm thick Ni, and the oxygen barrier layer 140 comprises 15 nm thick TiN. In another embodiment, the metal layer 120 comprises 15 nm thick Ni, the additive layer 130 comprises 1.5 nm thick Ti, and the oxygen barrier layer 140 comprises 15 nm thick TiN.

FIG. 2 illustrates an embodiment that does not include an optional barrier layer. When not using an optional barrier layer, the additive layer 130 is preferably deposited on the substrate 110 while the metal layer 120 is deposited on the additive layer 130, as illustrated in FIG. 2.

Turing now to FIG. 3, there is illustrated the structure of FIG. 1 after further processing according to embodiments described below. Shown in FIG. 3 is the substrate 110, wherein the substrate 110 now further includes a metal silicide layer 150 formed thereon. According to preferred embodiments of the invention, the metal silicide layer 150 includes an additive selected to prevent agglomeration of the metal silicide layer 150 upon subsequent thermal processing. On the metal silicide layer 150 there is a layer of unreacted materials and/or alloy reaction by-products, which collectively are referred to herein as an unreacted material layer 160. On the unreacted material layer 160 is the optional oxygen barrier layer 140. Forming the metal silicide layer 150 may include partially consuming the substrate 110 in the silicide reaction.

The preferred method to form the metal silicide layer 150 is a rapid thermal anneal (RTA), which is also referred to as a rapid thermal process (RTP). The RTA process is preferably performed in a gas atmosphere, e.g., He, Ar, N₂, or forming gas. The RTA temperature is between about 250 to 500° C. for a duration between about 10 and 180 seconds. In preferred embodiments, the RTA temperature is about 400° C. for about a 30 second duration. The RTA may be either a spike or a soak method.

Embodiments may further include an optional RTA soak step for grain growth and composition redistribution. The RTA soak temperature is about 450° C. for about 30 seconds.

After the RTA silicide forming step, the optional oxygen barrier layer 140 and the unreacted material layer 160 are removed using conventional etching techniques that are well known to those skilled in the art. For example, any wet etch process may be used when removing the optional oxygen barrier layer and the metal alloy layer from the structure. The chemical etchant employed in the wet etch process preferably removes the oxygen barrier layer 140 and the unreacted material layer 160 and leaves the metal silicide layer 150. A suitable etchant includes a mixture of hydrogen peroxide and nitric or sulfuric acid. Other chemical etchants can also be employed in the present invention. After the wet etch process, another RTA process could be implemented to change the salicide to a low resistivity structure. For example, another embodiment of the invention may include another RTA process to convert CoSi to CoSi₂.

After removing the unreacted material layer 160 and the oxygen barrier layer 140, conventional CMOS processing steps may be employed to fabricate other device regions such as gate regions on the structure.

The embodiments of the invention described above are exemplary and not limiting, and variations that are apparent to those skilled in the art that include the features of the invention are within the scope of the invention and the appended claims. Although embodiments of the present invention and their advantages have been described in detail, it should be understood that various changes, substitutions and alterations can be made herein without departing from the spirit and scope of the invention as defined by the appended claims.

For example, it will be readily understood by those skilled in the art that many of the features, functions, processes, and materials described herein may be varied while remaining within the scope of the present invention. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method for fabricating a metal silicide, the method comprising:
forming over a substrate a stacked arrangement of layers, wherein the stacked arrangement of layers comprises an additive layer and a metal layer;
annealing the stacked arrangement of layers to form a metal silicide layer on the substrate, wherein the metal silicide layer includes an additive from the additive layer; and
etching the stacked arrangement of layers to remove an unreacted material layer.

2. The method of claim 1, wherein the metal layer comprises a material selected from the group consisting essentially of Co, Ni, Ti, Pd, Pt, and combinations thereof.

3. The method of claim 1, wherein the additive layer comprises a material selected from the group consisting essentially of C, Al, Si, Sc, Ti, V, Cr, Mn, Fe, Co, Ni, Cu, Ge, Y, Zr, Nb, Mo, Ru, Rh, Pd, In, Sn, La, Hf, Ta, W, Re, Ir, Pt, Ce, Pr, Nd, Sm, Eu, Gd, Th, Dy, Ho, Er, Tm, Yb, Lu, and combinations thereof.

4. The method of claim 1, wherein the annealing comprises a rapid thermal anneal (RTA) process at about 250 to 850° C. for about 10 to 180 seconds.

5. A method for fabricating a metal silicide, the method comprising:
forming a stacked arrangement of layers comprising an additive layer on a substrate, and a metal layer on the additive layer;
annealing the stacked arrangement of layers to form a metal silicide layer on the substrate, wherein the metal silicide layer includes an additive from the additive layer; and
etching the stacked arrangement of layers to remove an unreacted material layer.

6. The method of claim 5, wherein the metal layer comprises a material selected from the group consisting essentially of Co, Ni, Ti, Pd, Pt, and combinations thereof.

7. The method of claim 5, wherein the additive layer comprises a material selected from the group consisting essentially of C, Al, Si, Sc, Ti, V, Cr, Mn, Fe, Co, Ni, Cu, Ge, Y, Zr, Nb, Mo, Ru, Rh, Pd, In, Sn, La, Hf, Ta, W, Re, Ir, Pt, Ce, Pr, Nd, Sm, Eu, Gd, Th, Dy, Ho, Er, Tm, Yb, Lu, and combinations thereof.

8. The method of claim 5, wherein the annealing comprises a rapid thermal anneal (RTA) process at about 250 to 850° C. for about 10 to 180 seconds.

9. The method of claim 8, wherein the RTA process has a duration of about 30 seconds.

10. The method of claim 5, wherein the additive comprises a material selected from the group consisting essentially of Co, Ni, Ti, Pd, Pt, Ta, Ge, Ir, Zr, and combinations thereof.

11. A method for fabricating a metal silicide, the method comprising:
forming a stacked arrangement of layers comprising a metal layer on a substrate, and an additive layer on the metal layer;
annealing the stacked arrangement of layers to form a metal silicide layer on the substrate, wherein the metal silicide layer includes an additive from the additive layer; and
etching the stacked arrangement of layers to remove an unreacted material layer.

12. The method of claim 11, wherein the metal layer comprises a material selected from the group consisting essentially of Co, Ni, Ti, Pd, Pt, and combinations thereof.

13. The method of claim 11, wherein the additive layer comprises a material selected from the group consisting essentially of C, Al, Si, Sc, Ti, V, Cr, Mn, Fe, Co, Ni, Cu, Ge, Y, Zr, Nb, Mo, Ru, Rh, Pd, In, Sn, La, Hf, Ta, W, Re, Ir, Pd, Ce, Pr, Nd, Sm, Eu, Gd, Th, Dy, Ho, Er, Tm, Yb, Lu, and combinations thereof.

14. The method of claim 11, wherein the forming a stacked arrangement of layers further comprises forming an oxygen barrier layer on the additive layer.

15. The method of claim 14, wherein the oxygen barrier layer comprises a material selected from the group consisting essentially of titanium nitride, silicon nitride, tantalum nitride, and combinations thereof.

16. The method of claim 11, wherein the annealing comprises a rapid thermal anneal (RTA) process at about 250 to 850° C. for about 10 to 180 seconds.

17. The method of claim 16, wherein the RTA process has a duration about 30 seconds.

18. The method of claim 11, wherein the additive comprises a material selected from the group consisting essentially of Co, Ni, Ti, Pd, Pt, Ta, Ge, Ir, Zr, and combinations thereof.
